(19) United States
(12) Patent Application Publication
(10) Pub. No.: US 2012/0125438 A1
(43) Pub. Date: May 24, 2012

(54) MANUFACTURING METHOD OF SOLAR BATTERY MODULE, AND SOLAR BATTERY MODULE MANUFACTURED WITH THAT MANUFACTURING METHOD

(76) Inventor: Akira Shimizu, Osaka-shi (JP)

(21) Appl. No.: 13/388,357

(22) PCT Filed: Aug. 3, 2010
(86) PCT No.: PCT/JP2010/063099

§ 371 Date: Feb. 1, 2012

(30) Foreign Application Priority Data
Aug. 4, 2009 (JP) 2009-181667

(51) Int. Cl. H01L 31/0203; H01L 31/18

(52) U.S. Cl. 136/259; 438/66; 257/E31.117

(57) ABSTRACT

A manufacturing method of a solar battery module includes a stacking step of arranging a peripheral sealing member at a peripheral portion of an upper surface of a glass substrate, arranging one or more solar cells on the upper surface of the glass substrate surrounded by the peripheral sealing member, arranging a first laminate film on an upper surface of the solar cells, and stacking a surface side plate glass above the first laminate film to face the glass substrate. The manufacturing method of a solar battery module further includes a sealing step of performing a lamination process by heating and applying pressure to the first laminate film in an air evacuation environment to obtain a translucent resin layer, and sealing the solar cells and the translucent resin layer in a space surrounded by the glass substrate, the surface side plate glass and the peripheral sealing member.

### TECHNICAL FIELD

The present invention relates to a manufacturing method of a solar battery module, and a solar battery module manufactured with the manufacturing method.

### BACKGROUND ART

There are solar battery modules having various types of structures depending on their applications and usage environments. One of such solar battery modules is a solar battery module having a laminated glass structure. This solar battery module has a structure in which a plurality of solar cells electrically connected to one another are sandwiched between a surface side plate glass and a back surface side plate glass, to seal the solar cells in the module.

In a solar battery module having this laminated glass structure, sunlight that has been transmitted through the surface side plate glass and entered the solar battery module passes through a translucent resin sealing layer in a portion where the solar cells are not provided, and reaches the back surface side plate glass. The sunlight that has reached the back surface side plate glass passes through the back surface side plate glass, and is transmitted to the outside of the solar battery module. Thus, the sunlight can also be obtained in a space at the side of the back surface of the solar battery module. As such, a solar battery module having the laminated glass structure is suitably utilized as a so-called lighting type solar battery module.

Prior documents that disclose a solar battery module having the above-described laminated glass structure include Japanese Patent Laying-Open No. 2003-26455 (PTL 1), Japanese Patent Laying-Open No. 2004-288677 (PTL 2), Japanese Patent Laying-Open No. 11-31834 (PTL 3), Japanese Patent Laying-Open No. 10-1334 (PTL 4), and Japanese Utility Model Laying-Open No. 61-177464 (PTL 5).

In solar battery modules having the laminated glass structure described in Japanese Patent Laying-Open No. 2003-26455 and Japanese Patent Laying-Open No. 2004-288677, solar cells are sealed with a translucent resin sealing layer, and the solar cells sealed with this translucent resin sealing layer are inserted and arranged in a subassembly including a surface side plate glass and a back surface side plate glass, to form the module.

In solar battery modules having the laminated glass structure described in Japanese Patent Laying-Open No. 11-31834, Japanese Patent Laying-Open No. 10-1334, and Japanese Utility Model Laying-Open No. 61-177464, a sealing portion is formed between two plate glasses, and solar cells are arranged in the sealing portion, which is filled with air or a filler.

A method of sealing a solar battery module having a laminated glass structure is now described. FIG. 12 is a cross-sectional view showing an example of a structure of a solar cell in which a sealing portion between two plate glasses has been filled with resin. As shown in FIG. 12, a solar cell 3 is arranged on an upper surface of a glass substrate 1. Solar cell 3 includes a surface electrode, a semiconductor layer, a back surface electrode and the like. A surface side plate glass 2 is arranged to face glass substrate 1. A space between glass substrate 1 and surface side plate glass 2 is filled with a resin member 11 to cover solar cell 3. A waterproof frame 12 is attached to side surfaces of glass substrate 1 and surface side plate glass 2, to seal solar cell 3.

FIG. 13 is a cross-sectional view showing another example of a structure of a solar cell in which a sealing portion between two plate glasses has been filled with resin. As shown in FIG. 13, solar cell 3 is arranged on the upper surface of glass substrate 1. A peripheral sealing member 5 is arranged on the upper surface of glass substrate 1 to surround solar cell 3. Surface side plate glass 2 is arranged to face glass substrate 1. A sealing portion formed by being surrounded by glass substrate 1, surface side plate glass 2 and peripheral sealing member 5 is filled with resin member 11.

FIG. 14 is a cross-sectional view showing an example of a structure of a solar cell in which a sealing portion between two plate glasses has been filled with air. As shown in FIG. 14, solar cell 3 is arranged on the upper surface of glass substrate 1. Peripheral sealing member 5 is arranged on the upper surface of glass substrate 1 to surround solar cell 3. Surface side plate glass 2 is arranged to face glass substrate 1. A sealing portion formed by being surrounded by glass substrate 1, surface side plate glass 2 and peripheral sealing member 5 is filled with air 13.

### CITATION LIST

### Patent Literature

PTL 1: Japanese Patent Laying-Open No. 2003-26455
PTL 2: Japanese Patent Laying-Open No. 2004-288677
PTL 3: Japanese Patent Laying-Open No. 11-31834
PTL 4: Japanese Patent Laying-Open No. 10-1334
PTL 5: Japanese Utility Model Laying-Open No. 61-177464

### SUMMARY OF INVENTION

### Technical Problem

When solar cell 3 is sealed with frame 12 from outside of glass substrate 1 and surface side plate glass 2 as shown in FIG. 12, the size of the solar battery module is increased. In the step of sealing the solar cell of the solar battery module shown in FIG. 13, the filling step with resin member 11 and the step of arranging peripheral sealing member 5 are separately performed, resulting in increased working man-hours.

For the solar battery module filled with air as shown in FIG. 14, condensation prevention is required since an air layer is included. Furthermore, in the solar battery module filled with air, it is difficult to secure load bearing strength of glass substrate 1 and surface side plate glass 2, and the glasses are not shatterproof, resulting in difficulty in using untempered glass as glass substrate 1 and surface side plate glass 2. In order to secure the strength of a solar battery module, therefore, a resin-filled type solar battery module having a laminated glass structure filled with resin is used.

In order to reduce working man-hours in a manufacturing method of the resin-filled type solar battery module, the filling step with resin member 11 and the step of arranging peripheral sealing member 5 could be included in the step of arranging surface side plate glass 2 to face glass substrate 1. FIG. 15A is a cross-sectional view showing a step of stacking a resin member 14, peripheral sealing member 5 and surface side plate glass 2 on glass substrate 1. FIG. 15B is a cross-sectional view showing a state where a lamination process is being performed. FIG. 15C is a cross-sectional view showing a state after the lamination process.

As shown in FIG. 15A, resin member 14 and peripheral sealing member 5 are arranged on the upper surface of glass substrate 1 having one or more solar cells 3 arranged thereon, and surface side plate glass 2 is arranged thereabove to face glass substrate 1.

As shown in FIG. 15B, in an air evacuation environment, pressure is applied to surface side plate glass 2 from the side of its upper surface in a direction indicated with arrows. Air 6 within the sealing portion formed by being surrounded by glass substrate 1, surface side plate glass 2 and peripheral sealing member 5 is evacuated until a lower surface of surface side plate glass 2 comes in contact with an upper surface of peripheral sealing member 5. After surface side plate glass 2 comes in contact with peripheral sealing member 5, there is no path for evacuating air 6 within the sealing portion to the outside, and thus air 6 within the sealing portion cannot be sufficiently evacuated.

As shown in FIG. 15C, resin member 14 that has been heated becomes a translucent resin layer 15, whereas air 6 remains as bubbles in the sealing portion. If there are bubbles in the sealing portion, the bubbles are thermally expanded when the solar battery module is heated with sunlight, causing deterioration such as occurrence of a crack in peripheral translucent resin layer 15. When translucent resin layer 15 is deteriorated, it is difficult to maintain performance of solar cell 3.

The present invention was made in view of the above problems, and an object of the present invention is to provide a manufacturing method of a solar battery module, capable of preventing bubbles from remaining in a sealing portion and reducing working man-hours in a manufacturing process, and a solar battery module manufactured with the manufacturing method.

### Solution to Problem

A manufacturing method of a solar battery module according to the present invention includes a stacking step of arranging a peripheral sealing member at a peripheral portion of an upper surface of a first plate-like member, arranging one or more solar cells on the upper surface of the first plate-like member surrounded by the peripheral sealing member, arranging a resin member on an upper surface of the solar cells such that a height from the upper surface of the first plate-like member to an upper surface of the resin member is higher than a height from the upper surface of the first plate-like member to an upper surface of the peripheral sealing member, and stacking a second plate-like member above the resin member to face the first plate-like member. The manufacturing method of a solar battery module further includes a sealing step of performing a lamination process by heating and applying pressure to the resin member in an air evacuation environment to obtain a translucent resin layer, and sealing the solar cells and the translucent resin layer in a space surrounded by the first plate-like member, the second plate-like member and the peripheral sealing member by bringing the second plate-like member into contact with the peripheral sealing member by setting a height from the upper surface of the first plate-like member to an upper surface of the translucent resin layer to be equal to or lower than the height from the upper surface of the first plate-like member to the upper surface of the peripheral sealing member.

By manufacturing the solar battery module in this manner, during the lamination process, a gap can be secured between the lower surface of the second plate-like member and the upper surface of the peripheral sealing member by the resin member. Accordingly, the resin member can be melted by heating while the air within the sealing portion formed by being surrounded by the first plate-like member, the second plate-like member and the peripheral sealing member is sufficiently evacuated. When the resin member decreases in thickness while melting and filling in the sealing portion, the lower surface of the second plate-like member comes close to the upper surface of the peripheral sealing member. Lastly, the lower surface of the second plate-like member comes in contact with the upper surface of the peripheral sealing member, to seal the solar cells and the translucent resin layer in the sealing portion. As a result, generation of bubbles in the sealing portion is suppressed.

In the manufacturing method of a solar battery module according to the present invention, the resin member may include a group of sheet-like resin members having a plurality of stacked sheet-like resin members. In this case, by arranging the sheet-like resin members as appropriate by stacking, the lamination process can be performed while increasing the thickness of the resin member to secure a path of air evacuation from the sealing portion. Accordingly, the translucent resin layer can be formed while generation of bubbles in the sealing portion is suppressed.

In the manufacturing method of a solar battery module according to the present invention, one of the sheet-like resin members of a lowermost layer of the group of sheet-like resin members may be formed of a single sheet, and the other one or more sheet-like resin members may be arranged in contact with an upper surface of the one of the sheet-like resin members of the lowermost layer. In this case, by arranging the other one or more sheet-like resin members as appropriate by stacking on the upper surface of the one of the sheet-like resin members of the lowermost layer, the lamination process can be performed while increasing the thickness of the resin member to secure a path of air evacuation from the sealing portion. Accordingly, the translucent resin layer can be formed while generation of bubbles in the sealing portion is suppressed.

In the manufacturing method of a solar battery module according to the present invention, the other one or more sheet-like resin members may be arranged in a distributed manner with a space therebetween on the upper surface of the one of the sheet-like resin members of the lowermost layer. In this case, the other one or more sheet-like resin members are arranged in a distributed manner on the upper surface of the one of the sheet-like resin members of the lowermost layer, so that the second plate-like member can be arranged with stability on the upper surface of the sheet-like resin members.

In the manufacturing method of a solar battery module according to the present invention, one of the sheet-like resin members of a lowermost layer of the group of sheet-like resin members may be formed of a single sheet, and the other one or more sheet-like resin members may be arranged in contact with an upper surface of the one of the sheet-like resin members of the lowermost layer continuously around an entire periphery of the upper surface. In this case, the other one or more sheet-like resin members are stacked continuously around the entire periphery of the upper surface of the one of the sheet-like resin members of the lowermost layer. Thus, when the resin member melts by heating, the resin can be smoothly diffused to the outside of the one of the sheet-like resin members of the lowermost layer.

In the manufacturing method of a solar battery module according to the present invention, a gap may be formed between an outer periphery of the resin member and an inner periphery of the peripheral sealing member. In this case, when the resin member melts by heating, the resin can be smoothly diffused into a space between the outer periphery of the sheet-like resin member and the inner periphery of the peripheral sealing member.

In the manufacturing method of a solar battery module according to the present invention, the sheet-like resin member may have concave and convex portions formed on its surface. In addition, the concave and convex portions may be formed by embossing.

In the manufacturing method of a solar battery module according to the present invention, the resin member may include one or more block-like resin members. The block-like resin members may be formed in a shape of a rod. Alternatively, the block-like resin members may be formed in a shape of a polyhedron having a point.

In the manufacturing method of a solar battery module according to the present invention, during the lamination process in the sealing step, a pressure force onto the resin member may be increased in stages. Further, in the manufacturing method of a solar battery module according to the present invention, a plate made of resin, metal or ceramic may be used as the first plate-like member or the second plate-like member. Furthermore, in the manufacturing method of a solar battery module according to the present invention, one of ethylene vinyl acetate copolymer, polyvinyl butyral, another olefin-based resin and silicon resin may be used for the sheet-like resin members.

In the manufacturing method of a solar battery module according to the present invention, the peripheral sealing member may be made of a moisture-resistant material. The moisture-resistant material may be one of butyl tape, butyl sheet, hot butyl, moisture-resistant resin and resin with a metallic core. Further, in the manufacturing method of a solar battery module according to the present invention, a thickness of the translucent resin layer may be set to be equal to or lower than 80% of a thickness of the resin member before the lamination process.

### Advantageous Effects of Invention

In the present invention, the lamination process is performed by heating and applying pressure to the resin member in an air evacuation environment while holding the second plate-like member with the resin member thicker than the peripheral sealing member, thereby securing a gap between the lower surface of the second plate-like member and the upper surface of the peripheral sealing member by the resin member. Accordingly, the solar cell and the translucent resin layer can be sealed while the air within the sealing portion formed by being surrounded by the first plate-like member, the second plate-like member and the peripheral sealing member is sufficiently evacuated. As a result, generation of bubbles in the sealing portion is suppressed. Furthermore, by including the filling step with the resin member and the step of arranging the peripheral sealing member in the stacking step, working man-hours during a manufacturing process of the solar battery module can be reduced.

### BRIEF DESCRIPTION OF DRAWINGS

FIG. 1A is a cross-sectional view showing a step of stacking a first laminate film, a peripheral sealing member and a surface side plate glass on a glass substrate in a manufacturing method of a solar battery module according to a first embodiment of the present invention.

FIG. 1B is a cross-sectional view showing a state where a lamination process is being performed in the manufacturing method of a solar battery module according to the first embodiment.

FIG. 1C is a cross-sectional view showing a state after the lamination process in the manufacturing method of a solar battery module according to the first embodiment.

FIG. 2A is a cross-sectional view showing a step of stacking the first laminate film, the peripheral sealing member and the surface side plate glass on the glass substrate in a manufacturing method of a solar battery module according to a second embodiment of the present invention.

FIG. 2B is a cross-sectional view showing a state where a lamination process is being performed in the manufacturing method of a solar battery module according to the second embodiment.

FIG. 2C is a cross-sectional view showing a state after the lamination process in the manufacturing method of a solar battery module according to the second embodiment.

FIG. 3 is a plan view of a solar battery module after a stacking step according to a first arrangement example, the solar battery module being seen from below the surface side plate glass.

FIG. 4 is a plan view of a solar battery module after a stacking step according to a second arrangement example, the solar battery module being seen from below the surface side plate glass.

FIG. 5 is a plan view of a solar battery module after a stacking step according to a third arrangement example, the solar battery module being seen from below the surface side plate glass.

FIG. 6 is a plan view of a solar battery module after a stacking step according to a fourth arrangement example, the solar battery module being seen from below the surface side plate glass.

FIG. 7 is a plan view of a solar battery module after a stacking step according to a fifth arrangement example, the solar battery module being seen from below the surface side plate glass.

FIG. 8 is a plan view of a solar battery module after a stacking step according to a sixth arrangement example, the solar battery module being seen from below the surface side plate glass.

FIG. 9 is a plan view of a solar battery module after a stacking step according to a seventh arrangement example, the solar battery module being seen from below the surface side plate glass.

FIG. 10A is a cross-sectional view showing a step of stacking laminate blocks, the peripheral sealing member and the surface side plate glass on the glass substrate in a manufacturing method of a solar battery module according to a third embodiment of the present invention.

FIG. 10B is a cross-sectional view showing a state where a lamination process is being performed in the manufacturing method of a solar battery module according to the third embodiment.

FIG. 10C is a cross-sectional view showing a state after the lamination process in the manufacturing method of a solar battery module according to the third embodiment.

FIG. 11 is a plan view of the solar battery module after the stacking step in the manufacturing method of a solar battery module according to the third embodiment of the present invention, the solar battery module being seen from below the surface side plate glass.

FIG. 12 is a schematic cross-sectional view showing an example of a structure of a solar cell in which a sealing portion between two plate glasses has been filled with resin.

FIG. 13 is a schematic cross-sectional view showing another example of a structure of a solar cell in which the sealing portion between the two plate glasses has been filled with resin.

FIG. 14 is a schematic cross-sectional view showing an example of a structure of a solar cell in which the sealing portion between the two plate glasses has been filled with air.

FIG. 15A is a cross-sectional view showing a step of stacking a resin member, a peripheral sealing member and a surface side plate glass on a glass substrate.

FIG. 15B is a cross-sectional view showing a state where a lamination process is being performed.

FIG. 15C is a cross-sectional view showing a state after the lamination process.

### DESCRIPTION OF EMBODIMENTS

Manufacturing methods of a solar battery module in embodiments based on the present invention will be described with reference to the drawings. In the following embodiments, manufacturing methods of a solar battery module having a laminated glass structure will be described by way of example.

### First Embodiment

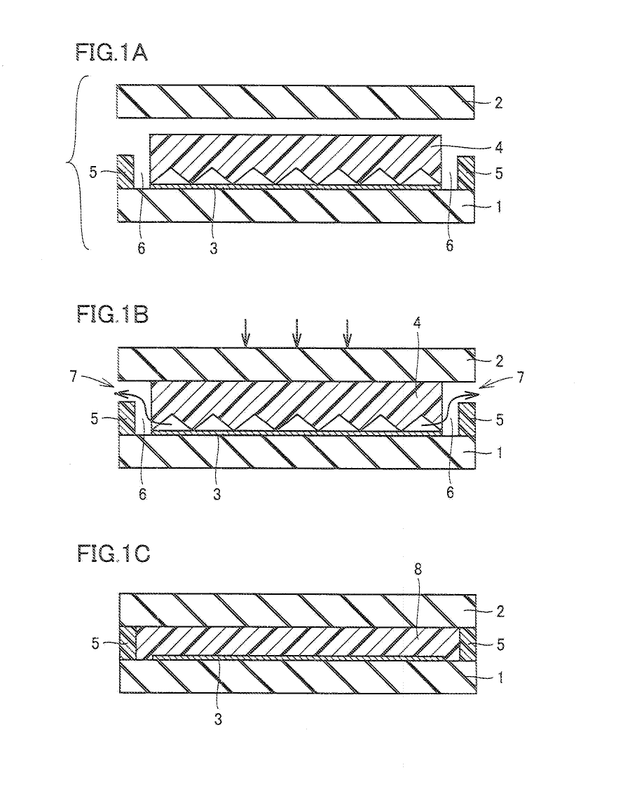

FIG. 1A is a cross-sectional view showing a step of stacking a first laminate film, a peripheral sealing member and a surface side plate glass on a glass substrate in a manufacturing method of a solar battery module according to a first embodiment of the present invention. FIG. 1B is a cross-sectional view showing a state where a lamination process is being performed in the manufacturing method of a solar battery module according to this embodiment. FIG. 1C is a cross-sectional view showing a state after the lamination process in the manufacturing method of a solar battery module according to this embodiment.

As shown in FIG. 1A, the solar battery module according to the first embodiment of the present invention mainly includes a glass substrate 1 as a first plate-like member, a surface side plate glass 2 as a second plate-like member, a solar cell 3 and a peripheral sealing member 5 arranged on an upper surface of glass substrate 1, and a resin member 4. The solar battery module has a substantially rectangular outer shape when viewed two-dimensionally from above glass substrate 1, and has one main surface configured as a light-receiving surface for receiving sunlight.

Solar cell 3 in this embodiment includes one or more thin film solar batteries having a surface electrode, a semiconductor layer having a semiconductor junction such as a pn junction and a back surface electrode formed on the upper surface of glass substrate 1. When solar cell 3 includes a plurality of thin film solar batteries, the thin film solar batteries are connected to one another by not-shown wiring. It should be noted that solar cell 3 is not limited to a thin film solar battery, but may be a crystalline solar battery including a wafer.

Surface side plate glass 2 is arranged above glass substrate 1 with a space therebetween so that its main surface faces glass substrate 1. For example, blue plate glass, white plate glass, figured glass, tempered glass, double tempered glass or wire glass may be utilized as glass substrate 1 and surface side plate glass 2. Glass substrate 1 and surface side plate glass 2 do not necessarily need to be the same type of plate glass, but may be different types of plate glasses. A type of plate glass to be used is selected as appropriate in consideration of an ambient environment in which the solar battery module is installed and the like. Surface side plate glass 2 arranged at the side of the light-receiving surface of the solar battery module is made of translucent plate glass.

Peripheral sealing member 5 is arranged at a peripheral portion of the upper surface of glass substrate 1 at the side facing surface side plate glass 2. This peripheral sealing member 5 has a surrounding shape in which its edge portions located at four ends of the solar battery module are connected to their adjacent edge portions at the respective ends, and has a predetermined space therein. Peripheral sealing member 5 is arranged to accommodate solar cell 3 in this internal space of peripheral sealing member 5.

The four edge portions of peripheral sealing member 5 are arranged to be located between the peripheral portion of glass substrate 1 and a peripheral portion of surface side plate glass 2. Peripheral sealing member 5 has an outer shape having substantially the same size as that of glass substrate 1 and surface side plate glass 2. Peripheral sealing member 5 has a predetermined thickness in a thickness direction of the solar battery module, and serves to separate glass substrate 1 and surface side plate glass 2 from each other in the thickness direction. A member made of glass, resin or metal having a thermal resistance such that peripheral sealing member 5 can at least withstand heat applied during a lamination process to be described later can be used as peripheral sealing member 5.

Next, on the upper surface of glass substrate 1, first laminate film 4 which is a resin member is arranged on an upper surface of solar cell 3 that has been arranged in the internal space of peripheral sealing member 5. Here, the size of first laminate film 4 is adjusted in advance such that first laminate film 4 is accommodated in the internal space of peripheral sealing member 5. Specifically, the size of first laminate film 4 is set to be the same as or to be substantially equal to the size of the internal space of peripheral sealing member 5.

In addition, first laminate film 4 is formed to be thicker than peripheral sealing member 5. Accordingly, first laminate film 4 is arranged such that a height from the upper surface of glass substrate 1 to an upper surface of first laminate film 4 is higher than a height from the upper surface of glass substrate 1 to an upper surface of peripheral sealing member 5.

Next, as shown in FIG. 1B, a stacked body obtained by performing the above stacking step is heated while pressure is applied thereto in a direction indicated with arrows from above surface side plate glass 2 in a vacuum state. Surface side plate glass 2 is held by first laminate film 4. Since first laminate film 4 is thicker than peripheral sealing member 5, a gap 7 is formed between a lower surface of surface side plate glass 2 being in contact with the upper surface of first laminate film 4 and the upper surface of peripheral sealing member 5.

First laminate film 4 may have concave and convex portions formed on its surface, as shown in FIG. 1B. The concave and convex portions may be formed by embossing. In this case, the sheet-like resin member has an increased thickness because of the concave and convex portions or embossed portions. Thus, even when a sheet-like resin member originally having a relatively small thickness before formation of the concave and convex portions or embossed portions is used, the lamination process can be performed while securing gap 7 serving as a path of air evacuation from a sealing portion. Although embossed portions in a triangular pyramid shape are formed on a bottom surface of the first laminate film in this embodiment, the shape of concave and convex portions or embossed portions to be formed is not limited to this shape. For example, embossed portions in a quadrangular pyramid shape may be formed on the upper surface or both surfaces of first laminate film 4.

Air 6 is present in the sealing portion formed by being surrounded by glass substrate 1, surface side plate glass 2 and peripheral sealing member 5 before a sealing step. First laminate film 4 has a predetermined hardness at room temperature, and when heated with an increase in temperature, becomes fluid with reduction in viscosity. In an initial stage of the lamination process where heating is started, first laminate film 4 maintains its shape, and gap 7 described above is present. Under a vacuum condition, air 6 is evacuated through gap 7 to the outside of the sealing portion.

As the heating progresses to some extent, first laminate film 4 becomes fluid with reduction in viscosity, causing surface side plate glass 2 and peripheral sealing member 5 to be gradually close to each other. Air 6 within the sealing portion keeps being evacuated in this state.

In a final stage of the lamination process with further progression of the heating, first laminate film 4 melts and flows around solar cell 3 without leaving a gap, and is then cured due to occurrence of a cross-linking reaction. As a result, as shown in FIG. 1C, a translucent resin layer 8 having a thickness equal to or smaller than that of peripheral sealing member 5 is formed in the sealing portion formed by being surrounded by glass substrate 1, surface side plate glass 2 and peripheral sealing member 5. Air 6 that was present in the sealing portion has been evacuated to the outside of the sealing portion, and thus hardly remains in the sealing portion.

In this manner, the height from the upper surface of glass substrate 1 to an upper surface of translucent resin layer 8 is set to be equal to or lower than the height from the upper surface of glass substrate 1 to the upper surface of peripheral sealing member 5. As a result, surface side plate glass 2 comes in close contact with peripheral sealing member 5, to seal solar cell 3 and translucent resin layer 8 in the sealing portion.

Translucent resin layer 8 is in close contact with glass substrate 1, surface side plate glass 2 and peripheral sealing member 5. A material less likely to cause damage to solar cell 3 in the lamination process needs to be used for translucent resin layer 8. In addition, it is preferable in terms of weather resistance to use a material resistant to degradation even when exposed to an environment of high temperature and high humidity over a long period of time.

From this point of view, a resin material containing ethylene vinyl acetate copolymer, polyvinyl butyral, silicon resin or the like can be suitably used, for example, as a resin material for translucent resin layer 8. These resin members have a sufficient hardness at room temperature, and become highly fluid with low viscosity by the heating during the lamination process. The resin members are thus smoothly diffused in the sealing portion, allowing translucent resin layer 8 to be formed evenly in the sealing portion.

Although a pressure force onto first laminate film 4 is constant during the lamination process in the sealing step described above in this embodiment, the pressure force may be increased in stages. In this case, the lamination process can include a stage where first laminate film 4 is melted by heating while low pressure is applied to surface side plate glass 2, and a subsequent stage where first laminate film 4 becomes translucent resin layer 8 while high pressure is applied to surface side plate glass 2. Surface side plate glass 2 may be cracked if high pressure is applied to surface side plate glass 2 from the beginning, and the possibility of such cracking can be reduced by increasing the pressure force in stages.

It is preferable that peripheral sealing member 5 be a member having a thermal resistance such that peripheral sealing member 5 can at least withstand the heat applied during the lamination process, as described above. It is also preferable that peripheral sealing member 5 be made of a moisture-resistant material. The moisture resistance of peripheral sealing member 5 reduces the amount of water absorbed into the sealing portion from outside. As a result, performance of solar cell 3 can be maintained for a long period of time to increase the life of the solar battery module.

For example, butyl tape, butyl sheet, hot butyl, moisture-resistant resin and resin with a metallic core can be used as the moisture-resistant material. Butyl tape, butyl sheet and hot butyl have a property of being deformed with crushed butyl when subjected to a predetermined or higher load. For this reason, when one of butyl tape, butyl sheet and hot butyl is used for peripheral sealing member 5, by setting peripheral sealing member 5 to have a thickness slightly greater than that of translucent resin layer 8, the butyl is crushed and deformed during lamination to the same thickness as that of translucent resin layer 8. Accordingly, the close contact between translucent resin layer 8 and glass substrate 1 and surface side plate glass 2 is readily secured.

When moisture-resistant resin is used for peripheral sealing member 5, even if translucent resin layer 8 partially flows into a space between peripheral sealing member 5 and glass substrate 1 or surface side plate glass 2 and is caught therein to result in slightly incomplete sealing, peripheral sealing member 5 absorbs water, thereby suppressing entry of moisture into the sealing portion.

As described above, during lamination using soft resin such as butyl for peripheral sealing member 5, the butyl in a portion near glass substrate 1 or surface side plate glass 2 may be crushed slightly too much, resulting in lowered dimensional accuracy of the thickness of the end portions of the solar battery module. When resin with a metallic core is used for peripheral sealing member 5, the dimensional accuracy of the thickness of the end portions of the solar battery module is improved since the resin has high deformation resistance. The improvement of the dimensional accuracy of these portions reduces troubles resulting from dimensions with regard to a jig or a frame for fixing the solar battery module on a mount.

Although glass substrate 1 is used as the first plate-like member and the surface side plate glass is used as the second plate-like member in this embodiment, a plate made of resin, metal or ceramic may be used as the first plate-like member or the second plate-like member. In this case, the first plate-like member or the second plate-like member is formed of a plate having a predetermined hardness, thereby suppressing hanging of the end portions of the second plate-like member when the second plate-like member is held by first laminate film 4. Accordingly, the lamination process can be performed while securing a gap between the second plate-like member and the peripheral sealing member to secure the path of air evacuation from the sealing portion. Therefore, translucent resin layer 8 can be formed while generation of bubbles in the sealing portion is suppressed.

It is preferable that the thickness of translucent resin layer 8 be equal to or lower than 80% of the thickness of first laminate film 4 before the lamination process. With a change of approximately 20% in thickness of the resin member between before and after the lamination process, before the lamination process, gap 7 serving as a path for evacuating air 6 from the sealing portion can be secured, and after the lamination process, the solar cell can be sealed such that surface side plate glass 2 is in close contact with peripheral sealing member 5 since the thickness of translucent resin layer 8 becomes equal to or smaller than that of peripheral sealing member 5.

By manufacturing the solar battery module as in this embodiment, during the lamination process, a gap can be secured between the lower surface of surface side plate glass 2 and the upper surface of peripheral sealing member 5 by first laminate film 4. Accordingly, first laminate film 4 can be melted by heating while the air within the sealing portion formed by being surrounded by glass substrate 1, surface side plate glass 2 and peripheral sealing member 5 is sufficiently evacuated. When first laminate film 4 decreases in thickness while melting and filling in the sealing portion, the lower surface of surface side plate glass 2 comes close to the upper surface of peripheral sealing member 5.

Lastly, the lower surface of surface side plate glass 2 comes in contact with the upper surface of peripheral sealing member 5, to seal solar cell 3 in the sealing portion. As a result, generation of bubbles in the sealing portion is suppressed. By suppressing the generation of bubbles in the sealing portion, performance of solar cell 3 can be maintained for a long period of time to increase the life of the solar battery module.

### Second Embodiment

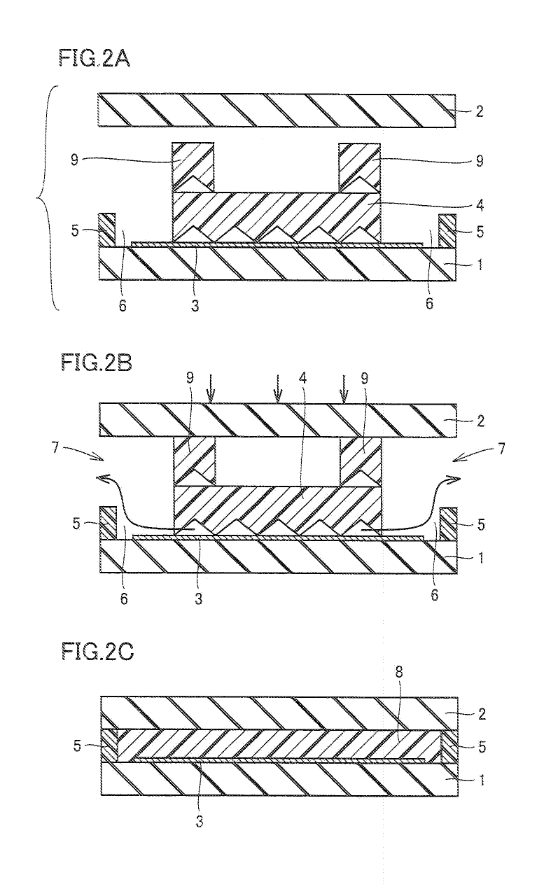

FIG. 2A is a cross-sectional view showing a step of stacking the first laminate film, the peripheral sealing member and the surface side plate glass on the glass substrate in a manufacturing method of a solar battery module according to a second embodiment of the present invention. FIG. 2B is a cross-sectional view showing a state where a lamination process is being performed in the manufacturing method of a solar battery module according to this embodiment. FIG. 2C is a cross-sectional view showing a state after the lamination process in the manufacturing method of a solar battery module according to this embodiment.

In the manufacturing method of a solar battery module according to the second embodiment of the present invention, as shown in FIG. 2A, second laminate films 9 are stacked on the upper surface of first laminate film 4 in the stacking step. Since a required amount of the resin member is constant, a peripheral portion of first laminate film 4 corresponding to the weight of second laminate films 9 has been eliminated.

In this embodiment, the resin member includes a group of sheet-like resin members having stacked laminate films 4 and 9 which are a plurality of sheet-like resin members. The remaining structure is similar to that of the first embodiment, and thus description thereof will not be repeated.

As shown in FIG. 2B, by arranging second laminate films 9, large gap 7 between the lower surface of surface side plate glass 2 and the upper surface of peripheral sealing member 5 can be secured during the lamination process in the sealing step as compared to the first embodiment. Since gap 7 serves as a path for evacuating air 6 within the sealing portion, securing large gap 7 in the initial stage of the lamination process allows smoother evacuation of air 6 within the sealing portion. Furthermore, since the peripheral portion of first laminate film 4 has been eliminated as described above, a space of that portion continues into gap 7 to form a path for evacuating air 6 within the sealing portion.

By the heating during the lamination process, first laminate film 4 and second laminate films 9 melt and spread around solar cell 3 without leaving a gap, and are then cured due to occurrence of a cross-linking reaction. As a result, as shown in FIG. 2C, translucent resin layer 8 having a thickness equal to or smaller than that of peripheral sealing member 5 is formed in the sealing portion formed by being surrounded by glass substrate 1, surface side plate glass 2 and peripheral sealing member 5. Air 6 that was present in the sealing portion has been evacuated to the outside of the sealing portion, and thus hardly remains in the sealing portion.

When second laminate film 9 is stacked on the upper surface of first laminate film 4 in this manner, the flow property of the resin member during heating, a load balance while surface side plate glass 2 is held by the resin member under pressure and the like vary depending on the shapes and arrangement of first laminate film 4 and second laminate film 9. Seven examples of the shapes and arrangement of first laminate film 4 and second laminate film 9 will be described.

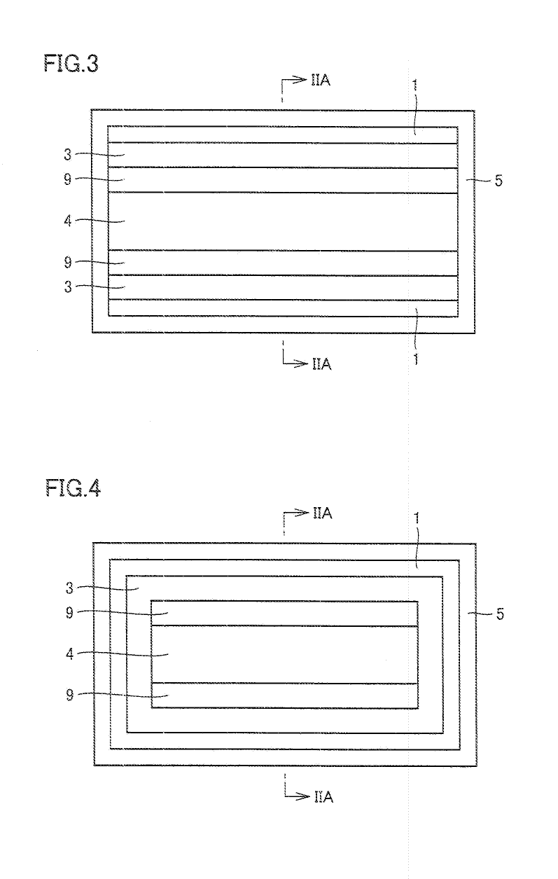

FIG. 3 is a plan view of a solar battery module after a stacking step according to a first arrangement example, the solar battery module being seen from below the surface side plate glass. As shown in FIG. 3, peripheral sealing member 5 is arranged at a peripheral portion of the upper surface of glass substrate 1. Solar cell 3 is arranged to be accommodated in the internal space of peripheral sealing member 5, and first laminate film 4 is arranged above solar cell 3. First laminate film 4, which is a sheet-like resin member of a lowermost layer of the group of sheet-like resin members, is formed of a single sheet.

First laminate film 4 has a length from one side to the other side of the inner wall of peripheral sealing member 5 in a longitudinal direction, and has a width such that a predetermined gap is formed from the inner wall of peripheral sealing member 5 in a width direction. Two second laminate films 9 are arranged with a space therebetween on opposite end portions in the width direction of the upper surface of first laminate film 4. Second laminate films 9 have a length from one side to the other side of the inner wall of peripheral sealing member 5 in the longitudinal direction.

By stacking first laminate film 4 and second laminate films 9 in this manner, and conducting heating while evacuating the air during the lamination process, the translucent resin layer can be formed to seal the solar battery cell while the generation of bubbles in the sealing portion is suppressed.

FIG. 4 is a plan view of a solar battery module after a stacking step according to a second arrangement example, the solar battery module being seen from below the surface side plate glass. The difference from the solar battery module shown in FIG. 3 is that, as shown in FIG. 4, the length of first laminate film 4 and second laminate films 9 is reduced such that a predetermined gap is formed from the inner wall of peripheral sealing member 5.

In this manner, the gap is formed between an outer periphery of first laminate film 4 and second laminate films 9 which are resin members and an inner periphery of peripheral sealing member 5. As a result, even when first laminate film 4 and second laminate films 9 are arranged in slightly deviated positions, part of first laminate film 4 and second laminate films 9 being pushed onto peripheral sealing member 5 is suppressed.

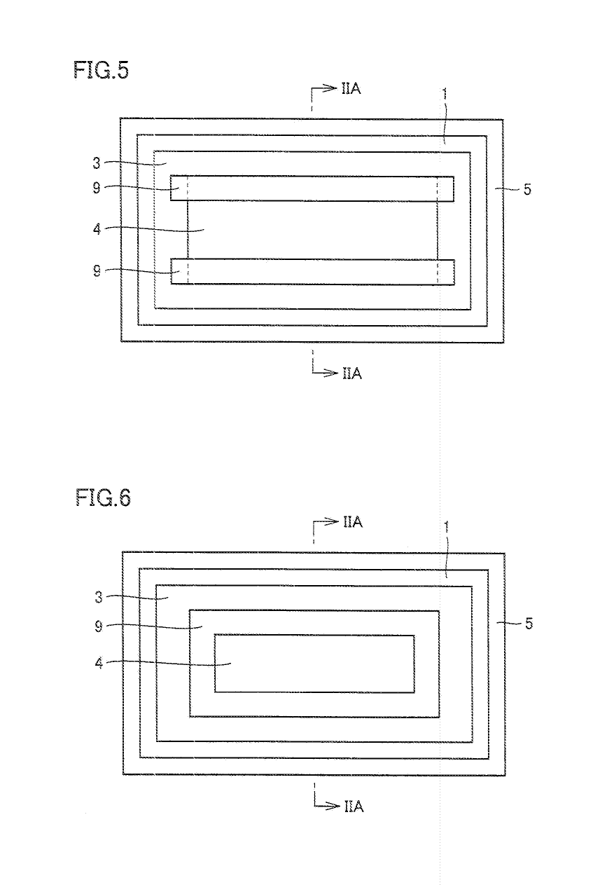

FIG. 5 is a plan view of a solar battery module after a stacking step according to a third arrangement example, the solar battery module being seen from below the surface side plate glass. The difference from the solar battery module shown in FIG. 4 is that, as shown in FIG. 5, the length of second laminate films 9 is longer that of first laminate film 4.

The resin melted during the lamination process is less likely to flow into portions near the corners at the inner peripheral side of peripheral sealing member 5. Thus, the translucent resin layer formed at the portions near the corners at the inner peripheral side of peripheral sealing member 5 tends to be insufficient. By increasing the length of second laminate films 9 to arrange the resin member at the portions near the corners at the inner peripheral side of peripheral sealing member 5 as described above, the translucent resin layer is more likely to be formed evenly in the sealing portion.

FIG. 6 is a plan view of a solar battery module after a stacking step according to a fourth arrangement example, the solar battery module being seen from below the surface side plate glass. The difference from the solar battery module shown in FIG. 4 is that, as shown in FIG. 6, second laminate film 9 is continuously arranged around the entire periphery of the upper surface of first laminate film 4. In this case, when first laminate film 4 and second laminate film 9 are melted by heating, the resin can be smoothly and evenly diffused.

Moreover, since second laminate film 9 being in contact with the surface side plate glass is arranged around first laminate film 4 in the stacking step, the surface side plate glass is held with stability.

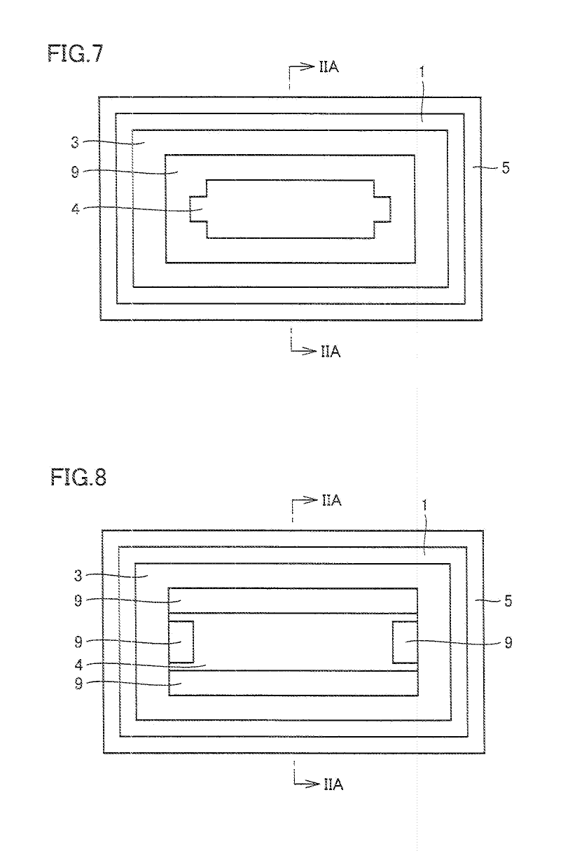

FIG. 7 is a plan view of a solar battery module after a stacking step according to a fifth arrangement example, the solar battery module being seen from below the surface side plate glass. The difference from the solar battery module shown in FIG. 6 is that, as shown in FIG. 7, second laminate film 9 is provided to extend to portions near the corners at the inner peripheral side of second laminate film 9. In this case, a large amount of the resin member is arranged at the portions near the corners at the inner peripheral side of peripheral sealing member 5, allowing the translucent resin layer to be readily formed evenly in the sealing portion.

FIG. 8 is a plan view of a solar battery module after a stacking step according to a sixth arrangement example, the solar battery module being seen from below the surface side plate glass. The difference from the solar battery module shown in FIG. 4 is that, as shown in FIG. 8, two second laminate films 9 are further arranged with a gap between end portions of the two second laminate films.

As a result, since second laminate films 9 being in contact with the surface side plate glass are arranged at an edge of first laminate film 4 in the stacking step, the surface side plate glass is held with stability. Moreover, since second laminate films 9 are arranged with a space therebetween, air present in a space at the inner peripheral side of second laminate films 9 is readily evacuated.

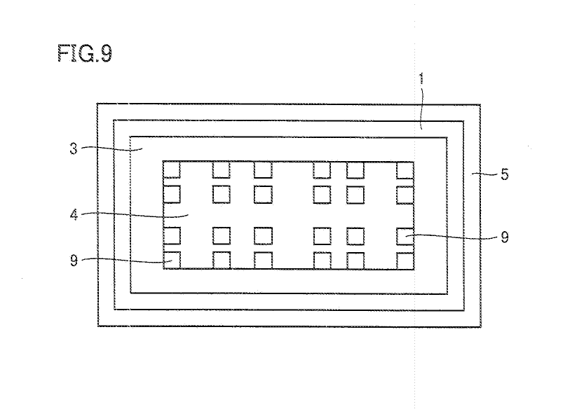

FIG. 9 is a plan view of a solar battery module after a stacking step according to a seventh arrangement example, the solar battery module being seen from below the surface side plate glass. As shown in FIG. 9, first laminate film 4, which is a sheet-like resin member of a lowermost layer of the group of sheet-like resin members, is formed of a single sheet, and the plurality of second laminate films 9 are arranged in a distributed manner with a space therebetween on the upper surface of the first laminate film.

As a result, since second laminate films 9 being in contact with the surface side plate glass are arranged in a distributed manner in the stacking step, the surface side plate glass is held with stability. Therefore, when a large surface side plate glass is stacked on the upper surface of second laminate films 9, occurrence of distortion of the surface side plate glass is suppressed.

By manufacturing the solar battery module as in this embodiment, during the lamination process, a gap can be secured between the lower surface of surface side plate glass 2 and the upper surface of peripheral sealing member 5 by first laminate film 4 and second laminate film 9. Accordingly, first laminate film 4 and second laminate film 9 can be melted by heating while the air within the sealing portion formed by being surrounded by glass substrate 1, surface side plate glass 2 and peripheral sealing member 5 is sufficiently evacuated. When first laminate film 4 and second laminate film 9 decrease in thickness while melting and filling in the sealing portion, the lower surface of surface side plate glass 2 comes close to the upper surface of peripheral sealing member 5.

Lastly, surface side plate glass 2 comes in contact with peripheral sealing member 5, to seal solar cell 3 in the sealing portion. As a result, generation of bubbles in the sealing portion is suppressed. By suppressing the generation of bubbles in the sealing portion, performance of solar cell 3 can be maintained for a long period of time to increase the life of the solar battery module.

### Third Embodiment

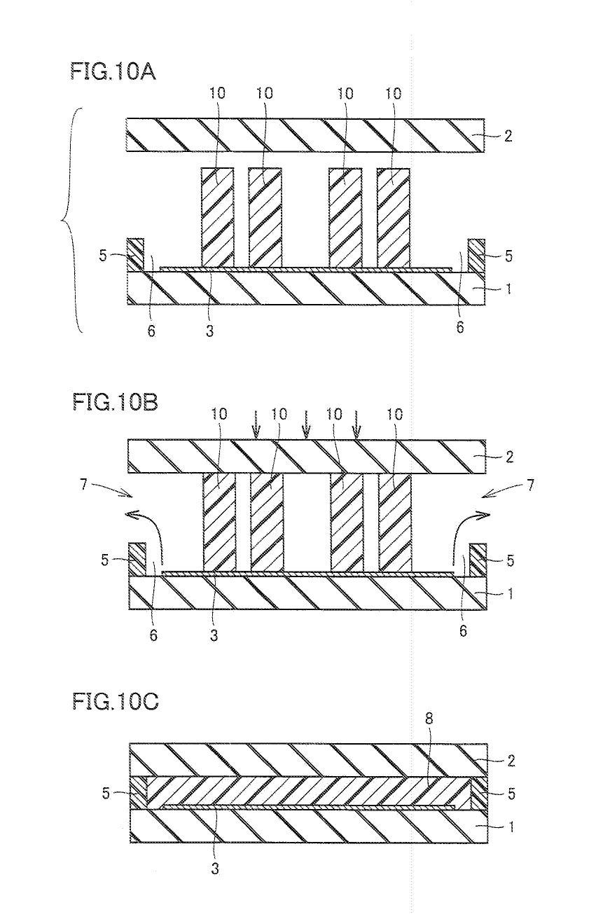

FIG. 10A is a cross-sectional view showing a step of stacking laminate blocks, the peripheral sealing member and the surface side plate glass on the glass substrate in a manufacturing method of a solar battery module according to a third embodiment of the present invention. FIG. 10B is a cross-sectional view showing a state where a lamination process is being performed in the manufacturing method of a solar battery module according to this embodiment. FIG. 10C is a cross-sectional view showing a state after the lamination process in the manufacturing method of a solar battery module according to this embodiment.

In the manufacturing method of a solar battery module according to the third embodiment of the present invention, as shown in FIG. 10A, laminate blocks 10 which are one or more block-like resin members are stacked above solar cell 3 in the stacking step. The remaining structure is similar to that of the first embodiment, and thus description thereof will not be repeated.

Since a block-like resin member has a thickness greater than that of a sheet-like resin member, the lamination process using a block-like resin member can be performed while securing a larger path of air evacuation from the sealing portion. Therefore, the translucent resin layer can be formed while the generation of bubbles in the sealing portion is further suppressed.

In this embodiment, each of laminate blocks 10 is formed in a shape of a rod having a round or quadrangular outer shape, such as a cylinder and a quadrangular prism. In this case, the lamination process can be performed by stacking surface side plate glass 2 on upper surfaces of laminate blocks 10 with stability while increasing the thickness of the resin member to secure the path of air evacuation from the sealing portion.

Alternatively, each of laminate blocks 10 may be formed in a shape of a polyhedron having a point such as a cone or a pyramid. In this case, laminate blocks 10 hold surface side plate glass 2 by point contact. Thus, when an uneven load is applied to laminate blocks 10, laminate blocks 10 are readily deformed depending on the load, thereby suppressing distortion of surface side plate glass 2 or variation of pressure applied to surface side plate glass 2 caused in such a case when laminate blocks 10 have varying heights.

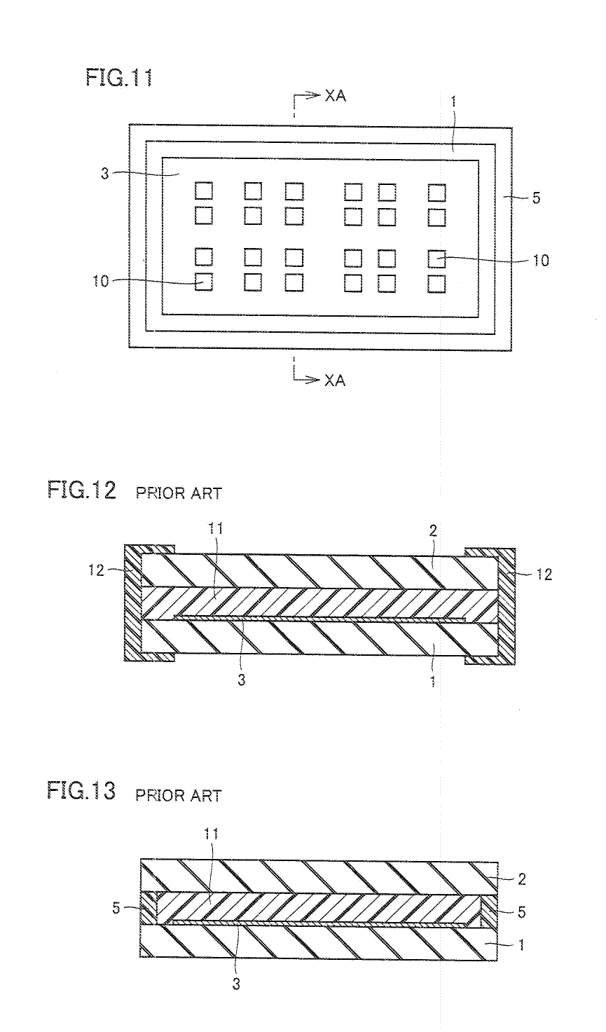

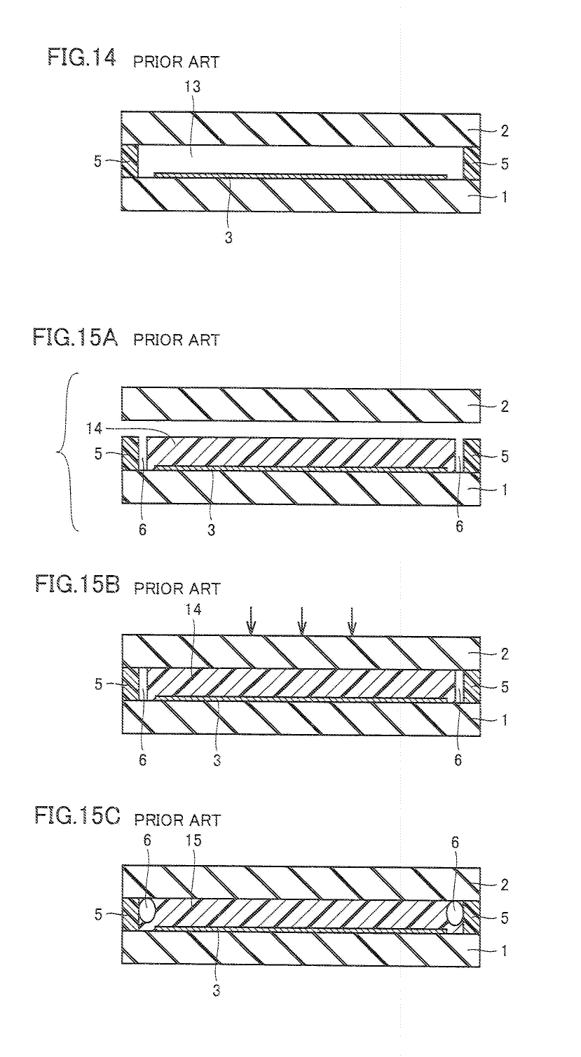

FIG. 11 is a plan view of the solar battery module after the stacking step in the manufacturing method of a solar battery module according to the third embodiment of the present invention, the solar battery module being seen from below the surface side plate glass. As shown in FIG. 11, peripheral sealing member 5 is arranged at the peripheral portion of the upper surface of glass substrate 1. Solar cell 3 is arranged to be accommodated in the internal space of peripheral sealing member 5, and laminate blocks 10 are arranged above solar cell 3.

By stacking laminate blocks 10 in this manner, and conducting heating while evacuating the air during the lamination process, the translucent resin layer can be formed to seal the solar battery cell while the generation of bubbles in the sealing portion is suppressed.

By manufacturing the solar battery module as in this embodiment, during the lamination process, a gap can be secured between the lower surface of surface side plate glass 2 and the upper surface of peripheral sealing member 5 by laminate blocks 10. Accordingly, laminate blocks 10 can be melted by heating while the air within the sealing portion formed by being surrounded by glass substrate 1, surface side plate glass 2 and peripheral sealing member 5 is sufficiently evacuated. When laminate blocks 10 decrease in thickness while melting and filling in the sealing portion, the lower surface of surface side plate glass 2 comes close to the upper surface of peripheral sealing member 5.

Lastly, surface side plate glass 2 comes in contact with peripheral sealing member 5, to seal solar cell 3 in the sealing portion. As a result, generation of bubbles in the sealing portion is suppressed. By suppressing the generation of bubbles in the sealing portion, performance of solar cell 3 can be maintained for a long period of time to increase the life of the solar battery module.

It should be understood that the embodiments disclosed herein are illustrative and do not serve as grounds for restrictive interpretation. Therefore, the technical scope of the present invention is defined by the terms of the claims, rather than merely interpreted by the embodiments above, and is intended to include any modifications within the scope and meaning equivalent to the terms of the claims.

### REFERENCE SIGNS LIST

1 glass substrate; 2 surface side plate glass; 3 solar cell; 4 first laminate film; 5 peripheral sealing member; 6 air; 7 gap; 8, 15 translucent resin layer; 9 second laminate film; 10 laminate block; 11, 14 resin member; 12 frame; 13 air.

1. A manufacturing method of a solar battery module, comprising:
a stacking step of arranging a peripheral sealing member at a peripheral portion of an upper surface of a first plate-like member, arranging one or more solar cells on the upper surface of said first plate-like member surrounded by said peripheral sealing member, arranging a resin member on an upper surface of said solar cells such that a height from the upper surface of said first plate-like member to an upper surface of said resin member is higher than a height from the upper surface of said first plate-like member to an upper surface of said peripheral sealing member, and stacking a second plate-like member above said resin member to face said first plate-like member; and
a sealing step of performing a lamination process by heating and applying pressure to said resin member in an air evacuation environment to obtain a translucent resin layer, and sealing said solar cells and said translucent resin layer in a space surrounded by said first plate-like member, said second plate-like member and said peripheral sealing member by bringing said second plate-like member into contact with said peripheral sealing member by setting a height from the upper surface of said first plate-like member to an upper surface of said translucent resin layer to be equal to or lower than the height from the upper surface of said first plate-like member to the upper surface of said peripheral sealing member.

2. The manufacturing method of a solar battery module according to claim 1, wherein
said resin member includes a group of sheet-like resin members having a plurality of stacked sheet-like resin members.

3. The manufacturing method of a solar battery module according to claim 2, wherein
in said stacking step, one of the sheet-like resin members of a lowermost layer of said group of sheet-like resin members is formed of a single sheet, and the other one or more sheet-like resin members are arranged in contact with an upper surface of said one of the sheet-like resin members of said lowermost layer.

4. The manufacturing method of a solar battery module according to claim 3, wherein
in said stacking step, said other one or more sheet-like resin members are arranged in a distributed manner with a space therebetween on the upper surface of said one of the sheet-like resin members of said lowermost layer.

5. The manufacturing method of a solar battery module according to claim 2, wherein
in said stacking step, one of the sheet-like resin members of a lowermost layer of said group of sheet-like resin members is formed of a single sheet, and the other one or more sheet-like resin members are arranged in contact with an upper surface of said one of the sheet-like resin members of said lowermost layer continuously around an entire periphery of the upper surface.

6. The manufacturing method of a solar battery module according claim 1, wherein
in said stacking step, said peripheral sealing member and said resin member are arranged to form a gap between an outer periphery of said resin member and an inner periphery of said peripheral sealing member.

7. The manufacturing method of a solar battery module according to claim 1, wherein
said resin member having concave and convex portions formed on its surface is used.

8. The manufacturing method of a solar battery module according to claim 7, wherein
said resin member having said concave and convex portions formed by embossing is used.

9. The manufacturing method of a solar battery module according to claim 1, wherein
said resin member including one or more block-like resin members is used.

10. The manufacturing method of a solar battery module according to claim 9, wherein
said block-like resin members having an outer shape of a rod are used.

11. The manufacturing method of a solar battery module according to claim 9, wherein
said block-like resin members having an outer shape of a polyhedron having a point are used.

12. The manufacturing method of a solar battery module according to claim 1, wherein
during said lamination process in said sealing step, a pressure force onto said resin member is increased in stages.

13. The manufacturing method of a solar battery module according to claim 1, wherein
a plate made of resin, metal or ceramic is used as said first plate-like member or said second plate-like member.

14. The manufacturing method of a solar battery module according to claim 2, wherein
one of ethylene vinyl acetate copolymer, polyvinyl butyral and silicon resin is used as a material for said sheet-like resin members.

15. The manufacturing method of a solar battery module according to claim 1, wherein
said peripheral sealing member is made of a moisture-resistant material.

16. The manufacturing method of a solar battery module according to claim 15, wherein
said moisture-resistant material is one of butyl tape, butyl sheet, hot butyl, moisture-resistant resin and resin with a metallic core.

17. The manufacturing method of a solar battery module according to claim 1, wherein
during said lamination process in said sealing step, a thickness of said translucent resin layer is set to be equal to or lower than 80% of a thickness of said resin member before the lamination process.

18. A solar battery module manufactured with the manufacturing method according to claim 1.
